(19) United States
(12) Patent Application Publication
(10) Pub. No.: US 2016/0208414 A1
(43) Pub. Date: Jul. 21, 2016

(54) METHOD FOR PRODUCING SiC EPITAXIAL WAFER

(71) Applicant: SHOWA DENKO K.K., Tokyo (JP)

(72) Inventors: Michiya ODAWARA, Chichibu-shi, Saitama (JP); Yutaka TAJIMA, Chichibu-shi, Saitama (JP); Daisuke MUTO, Chichibu-shi, Saitama (JP); Kenji MOMOSE, Chichibu-shi, Saitama (JP)

(73) Assignee: SHOWA DENKO K.K., Tokyo (JP)

(21) Appl. No.: 14/913,865

(22) PCT Filed: Aug. 13, 2014
(86) PCT No.: PCT/JP2014/071380

§ 371 Date: Feb. 23, 2016

(30) Foreign Application Priority Data
Sep. 4, 2013 (JP) 2013-183373

(51) Int. Cl. C30B 25/18; H01L 21/02; C30B 29/36

(52) U.S. Cl. CPC C30B 25/186; C30B 29/36; H01L 21/02378; H01L 21/02529; H01L 21/0262

(57) ABSTRACT

The method for producing an SiC epitaxial wafer according to the present invention includes: a step of vacuum baking a coated carbon-based material member at a degree of vacuum of 2.0×10⁻³ Pa or less in a dedicated vacuum baking furnace; a step of installing the coated carbon-based material member in an epitaxial wafer manufacturing apparatus; and a step of placing an SiC substrate in the epitaxial wafer manufacturing apparatus and epitaxially growing an SiC epitaxial film on the SiC substrate.

### TECHNICAL FIELD

The present invention relates to a method for producing an SiC epitaxial wafer. Priority is claimed on Japanese Patent Application No. 2013-183373, filed Sep. 4, 2013, the content of which is incorporated herein by reference.

### BACKGROUND ART

In general, in a process of manufacturing semiconductors and semiconductor devices and the like, a chemical vapor deposition method has been used as an industrial method for forming a thin film on a substrate. The semiconductors fabricated using this chemical vapor deposition method have been used in many industrial fields.

For example, silicon carbide (SiC) has the superior properties of having a band gap about three times wider, dielectric breakdown field strength about ten times stronger, and thermal conductivity about three times greater than silicon (Si), and is expected to be used in applications such as power devices, high-frequency devices or high-temperature operation devices.

SiC epitaxial wafers are normally used to manufacture such SiC devices. These SiC epitaxial wafers are fabricated by epitaxially growing an SiC single crystal thin film (SiC epitaxial layer) to serve as the active region of the SiC semiconductor device on the surface of an SiC single crystal substrate (SiC wafer) fabricated using a method such as sublimation recrystallization.

A chemical vapor deposition (CVD) device, which deposits and grows SiC epitaxial layers on the surfaces of heated SiC wafers while supplying a raw material gas into a chamber, is used as the epitaxial wafer manufacturing apparatus.

Epitaxial growth of SiC is carried out at a high temperature of 1,500° C. or higher. Therefore, as a member of the epitaxial wafer manufacturing apparatus, graphite (carbon) materials exhibiting excellent heat resistance as well as satisfactory thermal conductivity, and graphite substrates obtained by coating the surface with TaC or the like have been generally used.

However, these members composed of carbon-based materials typically contain a certain amount of nitrogen. Nitrogen becomes a dopant when incorporated into a compound semiconductor such as SiC. For this reason, when manufacturing a semiconductor device using the epitaxial wafer produced by the manufacturing apparatus having a member composed of a carbon-based material, its characteristics deteriorate.

Patent Document 1 discloses, in the apparatus for manufacturing an SiC epitaxial wafer, reduction of the nitrogen which is contained in a graphite susceptor by vacuum baking the graphite susceptor prior to epitaxial growth, and coating of a film of at least one of Si and SiC on the surface of the graphite susceptor after reduction of the contained nitrogen. In Patent Document 2, a method of producing a carbon-based material with a low concentration of nitrogen has been disclosed, in which a carbon-based material is subjected to a heat treatment under a halogen gas atmosphere at a pressure of 100 Pa or less and a temperature of 1,800° C. or higher to release the nitrogen in the carbon-based material, followed by cooling to room temperature under a rare gas atmosphere. Patent Document 3 discloses a susceptor in which at least a portion of the part for mounting the wafer is composed of tantalum carbide or a tantalum carbide-coated graphite material.

### CITATION LIST

### Patent Documents

[Patent Document 1] Japanese Unexamined Patent Application, First Publication No. 2003-086518

[Patent Document 2] Japanese Unexamined Patent Application, First Publication No. 2002-249376

[Patent Document 3] Japanese Unexamined Patent Application, First Publication No. 2006-060195

### SUMMARY OF INVENTION

### Technical Problem

However, even if an uncoated pure carbon-based material member is subjected to a process involving a low concentration of nitrogen as disclosed in Patent Document 2, when exposed to air, the carbon-based material member absorbs nitrogen in the air. Therefore, the member needs to be handled in a state of being cut off from the atmosphere containing nitrogen (such as air). In general, in the production site, the member is prevented from being exposed to air by actually performing vacuum baking in the epitaxial wafer manufacturing apparatus for forming a film. In this case, it becomes impossible to form a film by the epitaxial wafer manufacturing apparatus during vacuum baking, thereby considerably lowering the production efficiency.

In addition, even when wafers are brought into or taken out of the apparatus, it has been necessary to suppress the introduction of nitrogen gas into the furnace as much as possible and prevent the redeposition and penetration of nitrogen gas into the pure carbon-based material member by placing them in an Ar environment, such as a glove box, or conveying them into the furnace after performing an Ar replacement process once in a load lock chamber or the like.

On the other hand, as disclosed in Patent Document 1 and Patent Document 3, coating of the carbon-based material member with SiC, TaC or the like has been carried out conventionally as a means for suppressing the adverse effects of nitrogen gas on the carbon-based material member. However, during the production of epitaxial wafers, desorption of the nitrogen gas in the carbon-based material member occurred due to the defects, damages and the like that were caused by the coating formation, and controllability of the carrier concentration of the epitaxial film to be deposited and grown became unstable in some cases.

For example, with regard to a TaC-coated carbon-based material member which is used in a commercially available apparatus for manufacturing SiC epitaxial wafers, when its brand new product is mounted in the apparatus to produce an SiC epitaxial wafer, an initial background carrier concentration in the wafer is about 4×10¹⁷ cm⁻³ which is very high compared to the value of an appropriate background carrier concentration for the SiC epitaxial wafer used in the SiC device (equal to or less than 1×10¹⁶ cm⁻³).

Here, the “background carrier concentration” means a carrier concentration of SiC when a brand new carbon-based material member is mounted in the epitaxial wafer manufacturing apparatus to produce the SiC epitaxial film in an undoped manner.

Since the coated carbon-based material member is obtained by coating the carbon-based material member without gaps using grains of the order of 5 to 20 μm that are densely aggregated, sufficient desorption of the nitrogen contained in the coating which is in a brand new condition requires a long time of baking.

Therefore, in the production site, the aging treatment (vacuum baking) of about one week in the epitaxial wafer manufacturing apparatus has been carried out. During this period, production of the product (epitaxial wafer) could not be carried out and the production efficiency dropped significantly, which was a problem.

One of the main factors causing the surface defects that are to become killer defects for the SiC devices is the incorporation into the epitaxial film of the deposited materials on the inner wall of the apparatus and the members in the apparatus which come flying during the epitaxial growth process. There are less deposited materials immediately after the replacement of the TaC-coated carbon-based material member, and it is therefore advantageous for producing high quality epitaxial wafers with a low surface defect density. However, since it is necessary to perform the aging treatment immediately after the replacement of the members, it is impossible to carry out the fabrication of epitaxial wafers. In other words, there was also a problem that the period suitable for producing high quality epitaxial wafers cannot be used effectively.

The present invention has been made in view of the above circumstances, and has an object of providing a method for producing an epitaxial wafer that is easy to handle, the method capable of increasing the production efficiency and exposing the member used in the SiC epitaxial wafer manufacturing apparatus into the atmospheric environment after vacuum baking.

### Solution to Problem

The present invention provides the following means.

(1) A method for producing an SiC epitaxial wafer, the method including: a step of vacuum baking a coated carbon-based material member at a degree of vacuum of 2.0×10⁻³ Pa or less in a dedicated vacuum baking furnace; a step of installing the aforementioned coated carbon-based material member in an epitaxial wafer manufacturing apparatus; and a step of placing an SiC substrate in the aforementioned epitaxial wafer manufacturing apparatus and epitaxially growing an SiC epitaxial film on the SiC substrate.

(2) The method for producing an SiC epitaxial wafer according to (1), characterized in that the aforementioned degree of vacuum is 1.0×10⁻⁵ Pa or less.

(3) The method for producing an SiC epitaxial wafer according to either (1) or (2), characterized in that the aforementioned vacuum baking is carried out at a temperature of 1,400° C. or higher.

(4) The method for producing an SiC epitaxial wafer according to any one of (1) to (3), characterized in that the aforementioned vacuum baking is carried out for at least hours.

(5) The method for producing an SiC epitaxial wafer according to any one of (1) to (4), characterized in that the aforementioned vacuum baking is carried out until a nitrogen partial pressure at 1,500° C. is 1.0×10⁻⁷ Pa or less.

(6) The method for producing an SiC epitaxial wafer according to any one of (1) to (5), characterized in that the aforementioned coated carbon-based material member includes any one selected from the group consisting of a susceptor, a satellite, a sealing, and an exhaust ring.

(7) The method for producing an SiC epitaxial wafer according to any one of (1) to (6), characterized in that the aforementioned coating is formed using TaC or SiC.

### Advantageous Effects of Invention

According to the method for producing an SiC epitaxial wafer of the present invention, a configuration including the step of vacuum baking a coated carbon-based material member in a dedicated vacuum baking furnace has been adopted. For this reason, although the aging treatment (vacuum baking) of about one week in the epitaxial wafer manufacturing apparatus has been usually required after replacing the coated carbon-based material member, it is possible to eliminate the occupation time of the epitaxial wafer manufacturing apparatus. This makes it possible to utilize all of about one week for production which has usually been a production loss, and the production efficiency can be greatly improved.

A “dedicated baking furnace” is a furnace prepared, separately from the furnace used in the step of growing an epitaxial film, in order to carry out the baking under predetermined conditions. The expression “dedicated” does not refer to a particular structure of a furnace.

According to the method for producing an SiC epitaxial wafer of the present invention, a configuration including the step of vacuum baking a coated carbon-based material member at a degree of vacuum of 2.0×10⁻³ Pa or less in a dedicated vacuum baking furnace has been adopted. For this reason, although about one week of vacuum baking has been conventionally required in order to eliminate the incorporated nitrogen from the coated carbon-based material member, the vacuum baking can be carried out within a practical time of about 10 hours by baking at a temperature of 1,400° C. or higher, and it is possible to considerably reduce the time for vacuum baking.

The shortening of the vacuum baking time makes it possible to utilize a period in which the coated surface of the brand new, coated carbon-based material member is relatively clean. The main cause of the surface defects that are to become killer defects for the SiC devices is the deposited materials on the inner wall portion in the apparatus which become a particle generation source and come flying during the epitaxial growth process. The carbon-based material member immediately after the replacement with less deposited materials on the coated surface is highly advantageous in order to produce epitaxial wafers having a low surface defect density, and the epitaxial wafers of high crystallinity can be formed by utilizing this period.

Furthermore, in the coated carbon-based material member after the vacuum baking, the surface of the carbon-based material is closely protected by the coating. For this reason, if a purification treatment (degassing treatment and vacuum baking for desorbing the incorporated nitrogen) is once performed, the re-entering of nitrogen gas does not occur even when stored in the atmosphere for about several months, and the favorable background carrier concentration can be achieved. Therefore, it is possible to store the coated carbon-based material member after the purification treatment for a certain period of time. This is highly advantageous in terms of productivity.

In the present invention, the vacuum baking treatment of the coated carbon-based material member has been carried out in a dedicated baking furnace. For this reason, it is necessary to convey from the baking furnace to the epitaxial wafer manufacturing apparatus. As described above, the coated carbon-based material member can be exposed in the air because the graphite surface is closely protected by the coating. In other words, there is no need to worry about the environment at the time of conveyance, which is also highly advantageous in terms of workability. The coated carbon-based material member can be installed in an epitaxial wafer manufacturing apparatus from the dedicated baking furnace which is not connected to the epitaxial wafer manufacturing apparatus after being exposed to the atmosphere.

### BRIEF DESCRIPTION OF DRAWINGS

FIG. 1A is a graph showing the transition of the carrier concentration of the formed SiC wafer and FIG. 1B is a graph schematically showing the transition of the surface defect density, due to the replacement of the TaC-coated carbon-based material member in the SiC epitaxial wafer manufacturing apparatus.

FIG. 2A shows the TaC-coated graphite surface of a brand new product and FIG. 2B shows the surface after heating at 1,600° C. for 200 hours which are observed with an optical microscope.

FIG. 3A is a schematic sectional view and FIG. 3B is a schematic plan view showing an embodiment of a dedicated baking furnace employed in the present invention.

FIG. 4 is a schematic sectional view showing an example of a chemical vapor deposition apparatus used in the present invention.

FIG. 5 is a graph showing the results comparing the transitions of the carrier concentration against the cumulative heating time from immediately after the replacement of the SiC wafer which is formed using the TaC-coated carbon-based material member, with or without vacuum baking.

FIG. 6 is a graph showing the time variation of the partial pressure of a gas having a molecular weight of 28 (nitrogen) for each vacuum baking condition of the TaC-coated carbon-based material members.

FIG. 7 is a diagram showing the average values of the background carrier concentrations in the SiC epitaxial growth immediately after the vacuum baking and replacement of all or a portion of the TaC-coated carbon-based members. (a) is a value obtained when the members are not subjected to vacuum baking (initial state); (b) is a target value immediately after the member replacement; (c) is a value obtained when a set of all four types of members consisted of coated carbon-based material members is subjected to vacuum baking for 100 hours at 1,500° C.; (d) is a value obtained when a set of all four types of members consisted of coated carbon-based material members is subjected to vacuum baking for 200 hours at 1,500° C.; (e) is a value obtained when a set of all four types of members consisted of coated carbon-based material members is subjected to vacuum baking for 200 hours at 1,600° C.; (f) is a value obtained in a case where three types of carbon-based members with the exception of the susceptor are subjected to vacuum baking for 200 hours at 1,700° C. while only the susceptor is not subjected to vacuum baking; and (g) is a value obtained when a set of all four types of members consisted of coated carbon-based material members is subjected to vacuum baking for 200 hours at 1,700° C.

FIG. 8 is a graph showing the time variation of the partial pressure of a gas having a molecular weight of 28 (nitrogen) for each set of the TaC-coated carbon-based material members.

FIG. 9 is a graph showing the temperature dependence of the nitrogen partial pressure and the background carrier concentration in the case of performing vacuum baking for 200 hours at a degree of vacuum of 1.0×10⁻⁵ Pa.

### DESCRIPTION OF EMBODIMENTS

The configuration of a method for producing an epitaxial wafer applying the present invention will be described below with reference to the accompanying drawings. In the drawings used in the following description, the characteristic portions and components may be enlarged for easier understanding of characteristic features as a matter of convenience, and the dimensional ratio of each constituent element is not necessarily the same as the actual dimensional ratio. Materials, dimensions, and the like exemplified in the following description are merely examples, and the present invention is not limited thereto and can be carried out with appropriate modifications without departing from the gist of the invention.

The method for producing an epitaxial wafer of the present invention includes: a step of vacuum baking a coated carbon-based material member at a degree of vacuum of 2.0×10⁻³ Pa or less in a dedicated vacuum baking furnace; a step of installing the coated carbon-based material member in an epitaxial wafer manufacturing apparatus; and a step of placing an SiC substrate in the aforementioned epitaxial wafer manufacturing apparatus and epitaxially growing an SiC epitaxial film on the SiC substrate.

The carbon-based material in the expression “carbon-based material member” means a material mainly composed of carbon, such as graphite and pyrolytic graphite, in general. In other words, it means the materials in general that are identified by the names such as carbon materials.

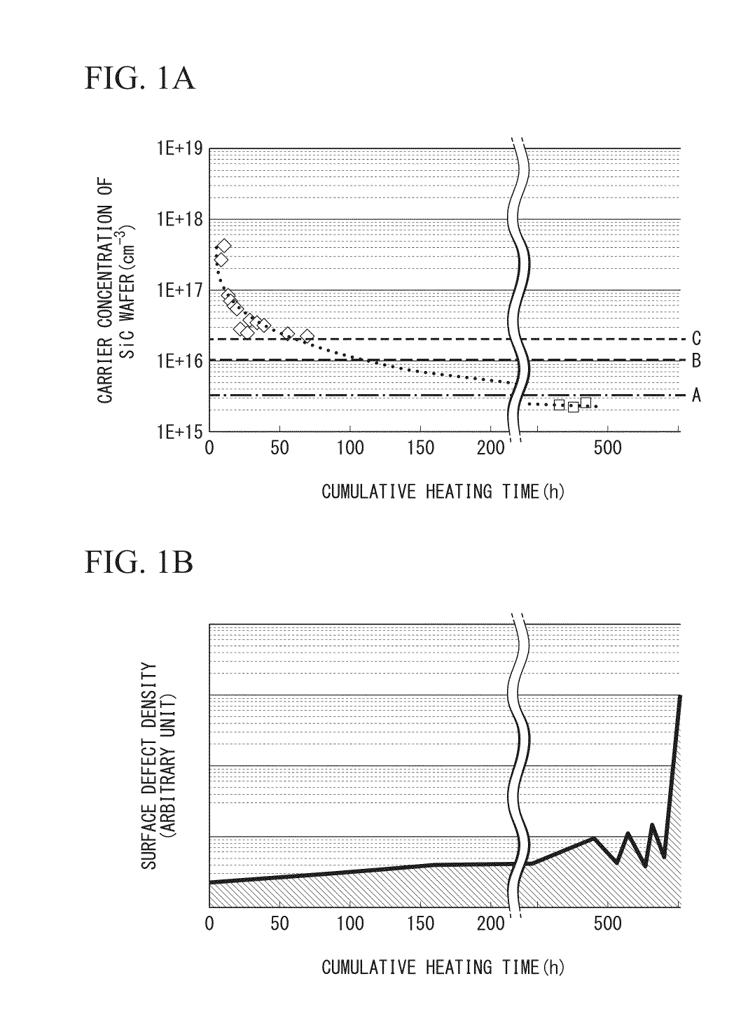

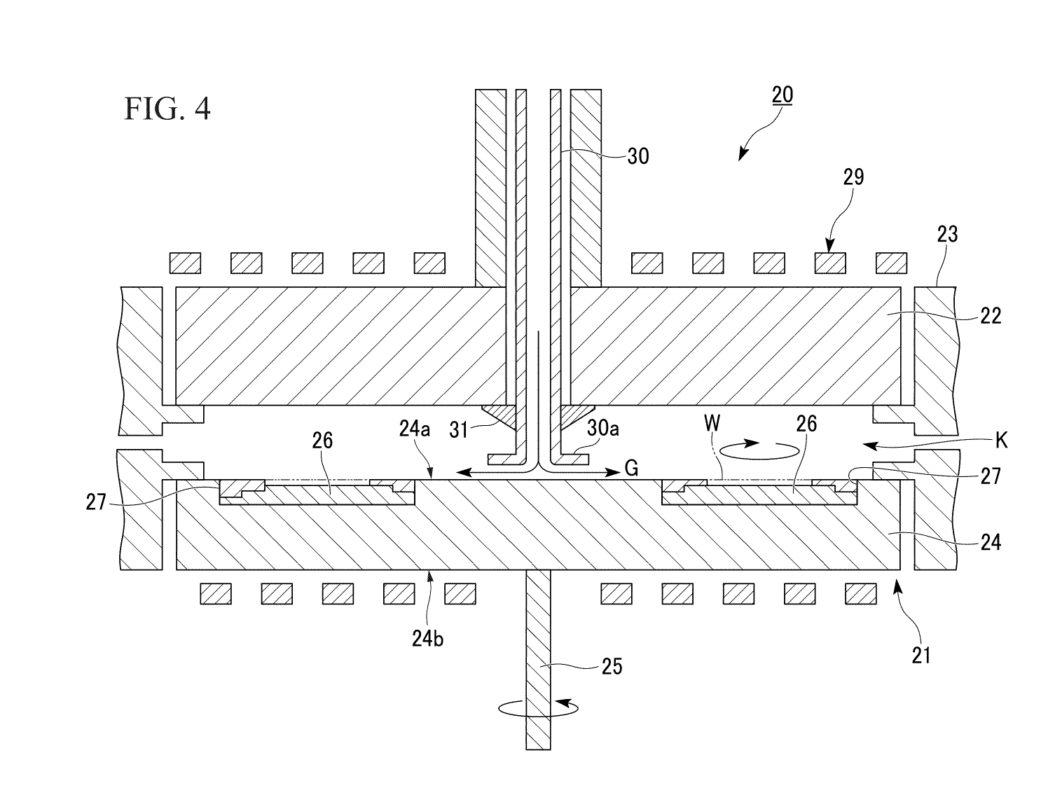

FIG. 1A is a graph showing the transition of the carrier concentration in the SiC epitaxial wafer (carrier concentration in the SiC epitaxial film) produced through the normal production cycle without performing a purification treatment (vacuum baking) using four types of members composed of TaC-coated carbon-based materials (a susceptor 24, a satellite 26, a sealing 22, and an exhaust ring 23, and if there are small components associated with the above members, they are included in the above members and considered as one unit), in a conventional SiC epitaxial wafer manufacturing apparatus, an example of which is shown in FIG. 4.

The vertical axis represents the carrier concentration in the SiC epitaxial wafer, and the horizontal axis represents the cumulative heating time (cumulative time of heating associated with the epitaxial growth). Immediately after the replacement of the above-mentioned four types of TaC-coated carbon-based material members is defined as 0 hour, and the transition of the background carrier concentration until after two months (carrier concentration in the epitaxial growth carried out without performing intentional doping) is shown. In FIG. 1A, plots of [symbol] and □ and the broken line represent the carrier concentration. The difference between the plots of [symbol] and □ is only that the thicknesses of the epitaxial films are different, and the thicknesses are in a relationship of [symbol] <□.

FIG. 1B represents the transition image of changes in the surface defect density in the SiC epitaxial film due to the downfall. Here, the term “downfall” refers to the deposited materials accumulated on the inner wall portion in the apparatus to become a particle generation source and come flying during the epitaxial growth process, that are incorporated into the epitaxial growth film to become defects. The horizontal axes of FIG. 1A and FIG. 1B are the same and represent a cumulative heating time by taking the time point at which the graphite member in the reactor is replaced with a brand new product as the starting point. The cumulative heating time is the time for epitaxial growth (which also includes baking if performed under the same heating conditions (temperature and degree of vacuum) as in the epitaxial growth). The degree of vacuum is in a state of reduced pressure of about 10⁴ Pa which is usually used during the epitaxial growth of SiC, and is a pressure condition much higher than the degree of vacuum used in the vacuum baking furnace in the present application.

In the example shown in FIG. 1A, the background of the carrier concentration decreased rapidly from the member replacement up to about 100 hours of the cumulative heating time, and stabilized thereafter. The background carrier concentration does not affect the thickness of a film grown by a single epitaxial growth, and even if the epitaxial growth in which doping is performed (not plotted in the drawings) is inserted in between, there is no effect on the trend. In other words, the background carrier concentration is more or less determined by the cumulative heating time.

On the other hand, in the example shown in FIG. 1B, the surface defects caused by the downfall tend to become unstable and increase from around the point at which the heating time of 500 hours has lapsed, and finally increase rapidly. It is thought that this is caused by an increase in the absolute amount of the deposited materials accumulated in the apparatus by repeating the film formation, the deposited materials coming back flying onto the wafer surface as particles during the film formation to increase the downfall density, and the degradation of the TaC coating to be detached from the members with the deposited materials.

In general, SiC epitaxial wafers need to have a background carrier concentration of 1.2×10¹⁵ cm⁻³ (line A shown in FIG. 1) or less in high-pressure resistant products, 1.0×10¹⁶ cm⁻³ (line B shown in FIG. 1) or less in normal products, and 1.1×10¹⁶ cm⁻³ (line C shown in FIG. 1) or less in general-purpose products, and the SiC epitaxial wafers formed during the period from the replacement of the members up to one week cannot be used even as normal products.

In addition, since the epitaxial wafers having surface defects caused by the downfall cannot be used as a product, the period in which the members can be used is limited with an upper limit with respect to the cumulative heating time.

In the production site, it was not possible to carry out the production of the epitaxial wafer in the SiC epitaxial wafer manufacturing apparatus for a certain period of time after the replacement of the members, and the situation was dealt with by performing the baking and dummy epitaxial growth to accumulate the cumulative heating time. When using the respective members of the epitaxial growth apparatus in the baking, considering the limitations of the apparatus and the adverse effects on the subsequent epitaxial growth, it is carried out under the same conditions of temperature and pressure as in the epitaxial growth. The entire period for the heat treatment using the epitaxial growth apparatus has been a production loss as an operating time that does not contribute to the production. As described above, with respect to the members, since there are constraints of the available cumulative heating time in view of an increase in the surface defects caused by the particles, the production loss for the stabilization of the background carrier concentration has been an extremely large problem.

However, the production loss has been considered as a cost required for manufacturing the SiC epitaxial wafers in the art, and the inventors of the present invention do not know any other studies for fundamentally solving the problem.

The method of the present invention for producing an SiC epitaxial wafer fundamentally solves this production loss.

Although the coated carbon-based material members are used in the method of the present invention for producing an SiC epitaxial wafer, in the coated member, as compared to the uncoated pure member, it is difficult to eliminate the gas incorporated in the member. In other words, in order to eliminate the gas contained in the member, it is disadvantageous to coat the member. Therefore, even if the member is coated, as disclosed in Patent Document 1, it has been considered desirable to coat the member after reducing the nitrogen contained in the member.

The inventors of the present invention have found that there are cases where the degassing of nitrogen contained in the coated carbon-based material member can be performed satisfactorily, and also discovered the vacuum baking conditions therefor. Further, it was discovered that it is possible to retain the effect of degassing even if the coated carbon-based material member is first subjected to the degassing of nitrogen thoroughly, and then exposed to a nitrogen-containing atmosphere. This is based on a new finding that the coated carbon-based material member of the present invention can be degassed by baking under certain conditions despite being coated, and there is substantially no adverse effect of nitrogen by the readsorption even if the member is exposed to a nitrogen-containing atmosphere (air).

In the method of the present invention for producing an SiC epitaxial wafer, in order to solve the above-mentioned problem of production loss, a dedicated vacuum baking furnace separate from the SiC epitaxial wafer manufacturing apparatus is used. Further, using the dedicated vacuum baking furnace, degassing (purification treatment) is carried out under predetermined vacuum baking conditions.

The degree of vacuum at the time of vacuum baking in the dedicated baking furnace is 2.0×10⁻³ Pa or less. The higher the degree of vacuum, the more advantageous for denitrification. The degree of vacuum is preferably not more than 1.0×10⁻⁴ Pa, more preferably not more than 1.0×10⁻⁵ Pa, still more preferably not more than 1.0×10⁻⁶ Pa, and particularly preferably not more than 1.0×10⁻⁷ Pa. Although there are no particular limitations on the lower limit, since the exhaust system becomes expensive in order to obtain a degree of vacuum higher than 1.0×10⁻⁸, a pressure equal to or higher than that is preferred. In addition, if the degree of vacuum is 2.0×10⁻³ Pa or less, it is possible to stably operate a vacuum device such as a turbo molecular pump and a quadrupole mass spectrometer (QMS). In general, a dry pump or the like is often used for the vacuum baking, although the vacuum baking in the present invention is performed at a high vacuum in order to desorb the incorporated nitrogen from the coated carbon-based material member. The degree of vacuum during the vacuum baking performed in the present invention is equal to or lower than the degree of vacuum that can be achieved only with a dry pump, and a turbo molecular pump, an ion getter pump, or the like which can achieve that degree of vacuum is used.

The temperature during the vacuum baking is preferably equal to or higher than 1,400° C., more preferably equal to or higher than 1,500° C., and even more preferably equal to or higher than 1,600° C. If the temperature is 1,400° C. or less, it takes a very long time to fully eliminate the contained nitrogen. The temperatures exceeding 1,700° C. cannot be easily achieved with usual low-cost resistance heating. For this reason, from the viewpoint of cost and the like, it is preferable to set the temperature to 1,700° C. or less. If the temperature is too high, the coating would be cracked and detached, and the SiC-coated member cannot be used at times. The heating at a temperature of 1,400° C. or higher can be realized by using what is commonly used, such as high frequency heating, in addition to the resistance heating.

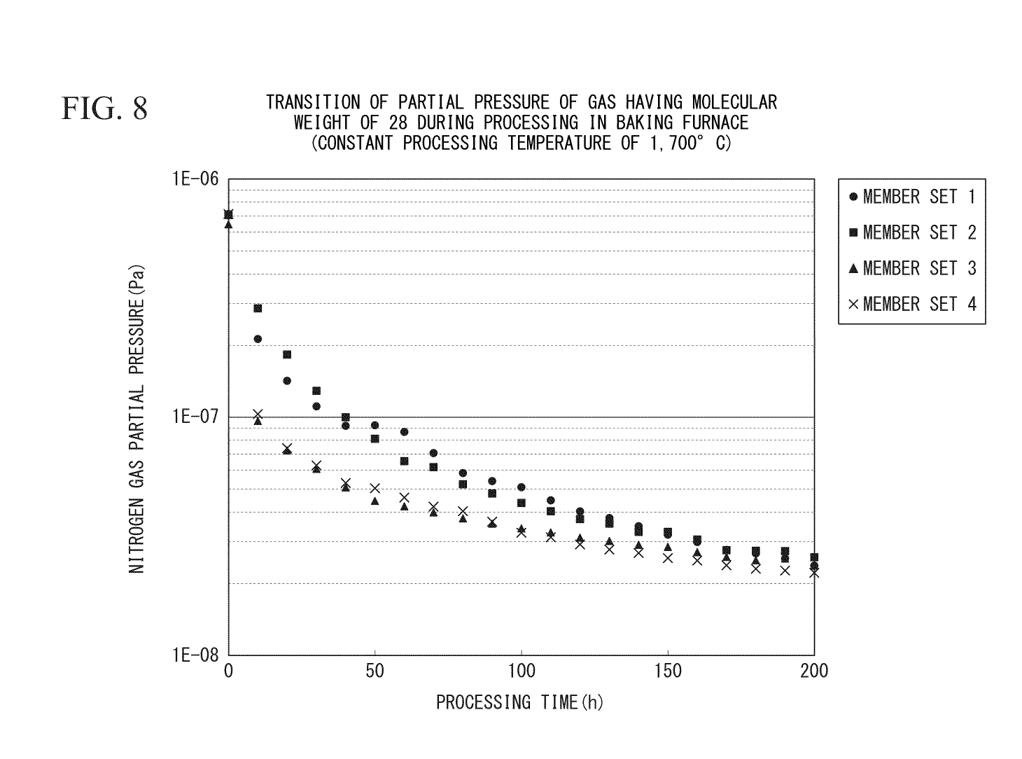

It is preferable to carry out the vacuum baking for a duration of at least 10 hours. This is because it can be considered that, if the vacuum baking is carried out for 10 hours or longer, the nitrogen gas partial pressure detected by the quadrupole mass spectrometer (QMS) is reduced to ½ to ⅛ of the initial level, and the contained nitrogen is thoroughly eliminated. The longer the vacuum baking time, the more the contained nitrogen can be desorbed. From the viewpoint of enhancing the effect of the degassing of nitrogen, the vacuum baking time is preferably equal to or longer than 20 hours, more preferably equal to or longer than 30 hours, and still more preferably even longer than that. In this respect, the preferred time can be derived, for example, by using the time shown on the horizontal axis of FIG. 8 as a measure. On the other hand, the shorter the better from the viewpoint of productivity. Thus, the vacuum baking may be performed by adopting the time determined from the viewpoint of productivity as an upper limit. For example, the upper limit may be 100 hours, 150 hours, 200 hours or the like.

It is preferable to carry out the vacuum baking until the nitrogen partial pressure reaches 1.0×10⁻⁷ Pa or less.

If it is 1.0×10⁻⁷ Pa or less, the background would be sufficiently low for using the SiC wafer as an SiC semiconductor device. The nitrogen partial pressure can be measured by a quadrupole mass spectrometer (QMS).

In the coated carbon-based material member, the surface of the carbon-based material is preferably coated with a thickness of 10 to 50 μm. If the thickness is less than 10 μm, the initial particle size of the coating material would be small, and the graphite material surface cannot be sufficiently covered. For this reason, the re-entering of the nitrogen gas that has been desorbed with effort occurs after the purification treatment. If the thickness exceeds 50 μm, cracks are likely to occur on the coating surface, which actually shortens the lifetime of the member.

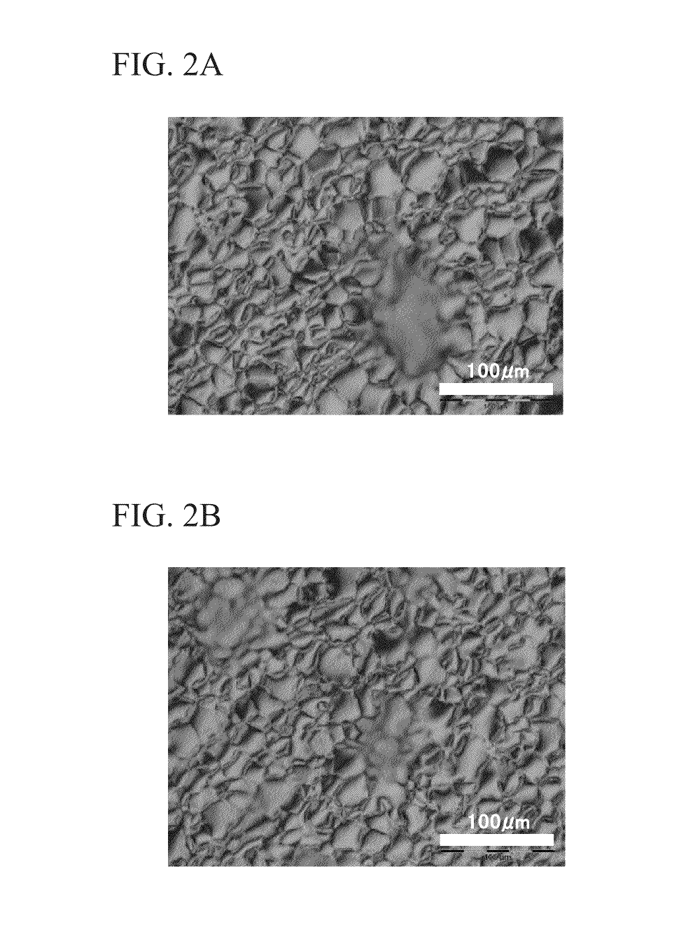

FIG. 2 shows an optical micrograph of a member coated with a TaC film having a thickness of 20 μm on the graphite surface. As shown in FIG. 2, it can be seen that grains having a diameter of about 20 μm are formed by aggregation. Each of the grains is arranged without gaps to cover the graphite surface, and the durability of the member is improved by this coating.

On the other hand, since the coating densely covers the surface of the carbon-based material member, desorption of the nitrogen gas incorporated in the member by vacuum baking is inhibited. For this reason, it is difficult to thoroughly desorb nitrogen gas by the degree of vacuum achieved by the generally used dry pump and the like (from 1 Pa to several hundred Pascal), and is therefore not efficient. In the present invention, it is possible to realize the desorption of nitrogen gas in a short period of time by carrying it out in a high vacuum environment.

Once the desorption of nitrogen gas is performed, the coated carbon-based material member can be taken out into the atmosphere. In the case of uncoated carbon-based material members, when taken out into the atmosphere, nitrogen in the atmosphere is absorbed once again into the members. On the other hand, in the case of coated carbon-based material members, since the surface of the carbon-based material members is densely protected by the coating, even when taken out into the atmosphere, the level of the contained nitrogen can be maintained at a low level. In other words, the vacuum baked carbon-based material members can be stored in air.

In addition, there is no need to take into account the surrounding environment during the conveyance from the dedicated baking furnace to the SiC epitaxial manufacturing apparatus.

For the coated carbon-based material members, for example, the carbon-based material members coated with SiC or TaC that are generally used for the epitaxial growth can be utilized.

### (Dedicated Baking Furnace)

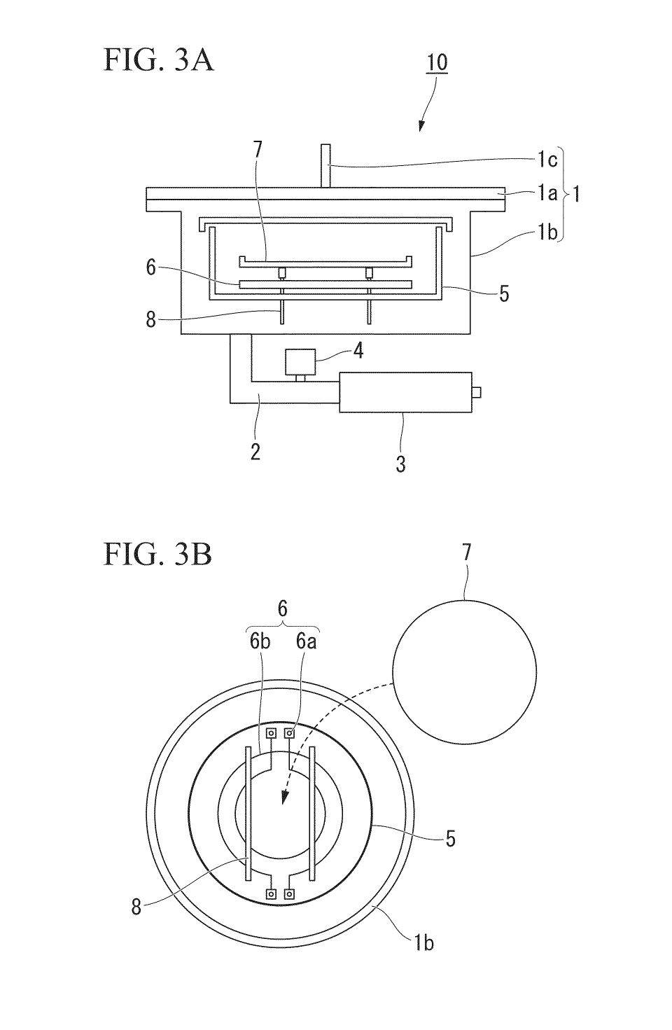

FIG. 3A is a schematic sectional view and FIG. 3B is a schematic plan view showing an example of a dedicated baking furnace used in the present invention.

The dedicated baking furnace used in the present invention may be, for example, a dedicated baking furnace 10 as shown in FIGS. 3A and 3B, and includes a chamber 1 made of SUS, an exhaust line 2 leading from the chamber 1, an exhaust system 3 composed of a dry pump and a turbo-molecular pump, and a quadrupole mass spectrometer (QMS) 4 for analyzing nitrogen gas during evacuation. It is possible to evacuate and reduce pressure in the chamber 1 made of SUS by the exhaust line 2 to the exhaust system 3.

The chamber 1 made of SUS is composed of a lid portion 1a, a main body portion 1b and a flange portion 1c, and includes a flow path in the periphery through which the running water flows for cooling (not shown). The lid portion 1a and the main body portion 1b are in close contact with each other using an O-ring or the like in order to prevent the entry of air during evacuation. The flange portion 1c is provided with a gas introduction nozzle and a monitor port for the radiation thermometer in the central portion (not shown). Inside the chamber, a heat shield plate 5, a heater 6, a tray 7 and rails 8 for holding the tray are included.

The heat shield plate 5 is made from 10 or more laminated metal plates having a high melting point, and is provided so as to thermally insulate the inside of the furnace of high temperature from the outside, and to hold the temperature inside the chamber 1 at a certain temperature.

The heater 6 is made of graphite and is a resistance heating type heater. In the case of a resistance heating system, it is possible to achieve a temperature of up to about 1,700° C. In addition, the heater 6 is divided into two regions composed of a heater 6a on the IN-side and a heater 6b on the OUT-side that deal with the atmosphere soaking in the furnace.

The tray 7 is made of graphite, and is intended to place the coated carbon-based material member for the epitaxial wafer manufacturing apparatus on the upper portion. When closing the lid portion 1b with respect to the main body portion 1c, the tray 7 is placed substantially horizontally on the rails 8 for holding the tray. The temperature of the tray 7 can be monitored by the monitor port for the radiation thermometer installed in the flange portion 1c.

The exhaust system 3 is composed of a dry pump and a turbo-molecular pump, and can generally realize a high degree of vacuum of about 10⁻¹ to 10⁻⁶ Pa. Typically, when performing the baking of a member (jig) to be installed in the epitaxial wafer manufacturing apparatus, the vacuum drawing is carried out by using only a dry pump or the like, and the vacuum drawing is not performed by using both a turbo-molecular pump and a dry pump. In the present invention, the vacuum baking is carried out by evacuating to a high vacuum using such an exhaust system.

When passing through the exhaust line 2, the air in the chamber which has been evacuated and depressurized by the exhaust system 3 passes through simultaneously the quadrupole mass spectrometer (QMS) 4 installed in the exhaust line. At this time, it is possible to analyze the exhausted degassed components and their partial pressures, and monitor the desorption level of the nitrogen gas on a regular basis.

### (Epitaxial Wafer Manufacturing Apparatus)

FIG. 4 is a schematic sectional view showing an example of an epitaxial wafer manufacturing apparatus used in the present invention.

An epitaxial wafer manufacturing apparatus used in the present invention is, for example, a CVD (chemical vapor deposition) apparatus 20 as shown in FIG. 4, and is intended to deposit and grow a film (not shown) on the surface of a heated wafer W, while supplying a raw material gas G into a chamber capable of decompression and evacuation (film forming chamber) which is not illustrated. For example, in the case of SiC epitaxial growth, those containing silane (SiH₄) as a Si source and propane (C₃H₈) as a carbon (C) source can be used as the raw material gas G, and those containing hydrogen (H₂) can be used as a carrier gas. FIG. 4 is a diagram showing a configuration of a main portion inside the reactor, and it is configured in such a manner that they are accommodated in a chamber made of SUS which is capable of decompression and evacuation (not shown).

More specifically, the CVD apparatus 20 is provided with, in the chamber, a mounting plate 21 on which a plurality of wafers W are placed, a sealing (top plate) 22 arranged to face the top surface of the mounting plate 21 so as to form a reaction space K with the mounting plate 21, and exhaust rings 23 positioned outside the mounting plate 21 and the sealing 22 and disposed so as to surround the periphery of the reaction space K. The exhaust rings 23 form a peripheral wall with respect to the reaction space K, and have a structure in which the carrier gas is evacuated from the reaction space K through a plurality of holes (exhaust holes) formed in the exhaust rings 23.

The mounting plate 21 has a disc-shaped susceptor (rotating base) 24 and a rotating shaft 25 attached to a central portion of a susceptor lower surface 24b, and the susceptor 24 is rotatably supported together with the rotating shaft 25. On a susceptor upper surface 24a except for the portions where the satellites 26 are present, one or a plurality of cover discs (not shown) that are thin plate-like members covering a portion or most of the upper surface may be disposed. The cover discs can prevent the SiC deposits from adhering directly to the susceptor 24. The cover discs are included in a susceptor unit as a part associated with the susceptor.

In addition, on the side of the susceptor upper surface 24a, a plurality of recessed accommodating portions 27 are provided for accommodating the satellites (disc-shaped wafer support tables) 26 on which the wafers W are placed.

The accommodating portions 27 form a circular shape in plan view (when viewed from the susceptor upper surface 24a side) and provided side by side in plural at regular intervals in the circumferential direction (rotation direction) of the susceptor 24. In FIG. 4, a case in which six accommodating portions 27 are provided side by side at regular intervals is illustrated.

The satellites 26 have an outer diameter slightly smaller than the inner diameter of the accommodating portions 27 of the susceptor 24, and are rotatably supported by the accommodating portions 27 of the susceptor 24 around the respective central axes by being supported from below by pin-shaped small projections (not shown) present in the central portion of the bottom surface of the accommodating portions 27.

The upper surface of the wafer W after the mounting of the wafer is preferably present on the same plane as the susceptor upper surface 24a, or in the lower side than that. If the wafer W is higher than the susceptor upper surface 24a, the disturbance of the flow of the raw material gas (disturbance of the laminar flow) at the wafer edge is likely to occur, and the characteristics of the film formed at the wafer edge may differ from those in the inner side. The satellite unit may be configured in such a manner that a ring as shown in the drawing is arranged on the outer periphery of the satellite upper surface, and the wafer is fixed to the satellite center portion.

The mounting plate 21 employs the so-called planetary (rotation and revolution) system. In the mounting plate 21, when the rotating shaft 25 is rotated by a driving motor which is not illustrated, the susceptor 24 is rotated about the central axis. A plurality of wafer support tables 26 are configured so as to be rotated about the respective central axes (not shown) by the supply of a driving gas separate from the raw material gas between each of the lower surfaces of the satellites 26 and the accommodating portions. As a result, it is possible to carry out film formation uniformly on each wafer W mounted on the plurality of wafer support tables 26.

The sealing 22 is a disc-shaped member having a diameter substantially the same as that of the susceptor 24 of the mounting plate 21, and forms a flat reaction space K with the mounting plate 21 while facing the upper surface of the susceptor 24. The exhaust ring 23 is a ring-shaped member surrounding the outer peripheral portions of the mounting plate 21 and the sealing 22. The exhaust ring 23 is making the reaction space K to communicate with the exhaust space present on the outside, through a plurality of holes (shown as through holes on both ends in the drawing).

The CVD apparatus 20 includes induction coils 29 for heating the mounting plate 21 and the sealing 22 by high frequency induction heating as a heating means for heating the wafer W mounted on the satellite 26. The induction coils 29 are respectively arranged by facing each other in close proximity on the lower surface of the mounting plate 21 (susceptor 24) and the upper surface of the sealing 22.

In the CVD apparatus 20, it is configured so that when a high frequency current is supplied to the induction coils 29 from a high frequency power source which is not illustrated, the mounting plate 21 (the susceptor 24 and the satellites 26) and the sealing 22 are heated by high frequency induction heating, and the wafer W mounted on the satellite 26 can be heated by the radiation from these mounting plate 21 and the sealing 22 and the heat conduction and the like from the satellites 26.

For the mounting plate 21 (the susceptor 24 and the satellites 26), the sealing 22 and the exhaust ring 23, those composed of graphite (carbon) materials excellent in heat resistance and having favorable thermal conductivity can be used as a material suitable for high frequency induction heating. Furthermore, those in which the surface is coated with SiC, TaC or the like can be suitably used, since the generation of particles and the like from graphite (carbon) can be prevented.

Nitrogen is contained in the mounting plate 21 (the susceptor 24 and the satellites 26) and the sealing 22 composed of graphite, and the nitrogen acts as a dopant with respect to the compound semiconductors including the SiC semiconductors, and therefore significantly degrades the characteristics of the SiC devices to be fabricated. For this reason, it is necessary to carry out the vacuum baking in order to reduce the nitrogen. In the present invention, by performing the vacuum baking in a dedicated baking furnace, it is possible to eliminate the occupancy time of the epitaxial wafer manufacturing apparatus due to the vacuum baking and also to considerably reduce the time required for the vacuum baking.

The heating means is not limited to those employing high frequency induction heating as described above, and those employing resistance heating or the like may be used. In addition, the configuration is not limited to those in which the heating means is disposed on the lower surface side of the mounting plate 21 (susceptor 24) and the upper surface side of the sealing 22, and it is also possible to adopt a configuration in which the heating means is disposed only on either one side.

The CVD apparatus 20 includes a gas introduction tube (gas inlet) 30 for introducing the raw material gas G into the reaction space K from the central portion of the upper surface of the sealing 22 as a gas supply means for supplying the raw material gas G into the chamber. The gas introduction tube 30 is formed into a cylindrical shape, and its distal end (lower end portion) is arranged so as to face the inside of the reaction space K in a state of penetrating through a support ring 31 having a circular opening which is provided in the central portion of the sealing 22.

A flange portion 30a that protrudes in the diameter expanding direction is provided in the distal end (lower end portion) of the gas introduction tube 30. The flange portion 30a is for allowing the raw material gas G emitted vertically downward from the lower end portion of the gas introduction tube 30 to flow in a radial manner in the horizontal direction between the opposing susceptor 24.

Further, in the CVD apparatus 20, by allowing the raw material gas G discharged from the gas introduction tube 30 to flow radially from the inside of the reaction space K toward the outside, it becomes possible to supply the raw material gas G in parallel to the surface of the wafer W. It is possible to discharge the gas that is no longer needed in the chamber from the exhaust holes provided in the exhaust ring 23 to the outside of the chamber.

Here, it is configured so that although the sealing 22 is heated at a high temperature by the induction coils 29, the inner peripheral portion thereof (the central portion side which is supported by the support ring 31) is not in contact with the gas introduction tube 30 which is kept at a low temperature in order to introduce the raw material gas G. In addition, the sealing 22 is supported vertically upward, on the support ring (supporting member) 31 attached to the outer peripheral portion of the gas introduction tube 30, through the inner peripheral portion thereof being mounted thereon. Furthermore, it is configured so that the sealing 22 can be moved in the vertical direction.

### EXAMPLES

Hereafter, the effects of the present invention will be described in further detail using examples. Note that the present invention is in no way limited to the examples described below, and can be configured with various modifications, where appropriate, within a range that does not alter the scope and spirit thereof.

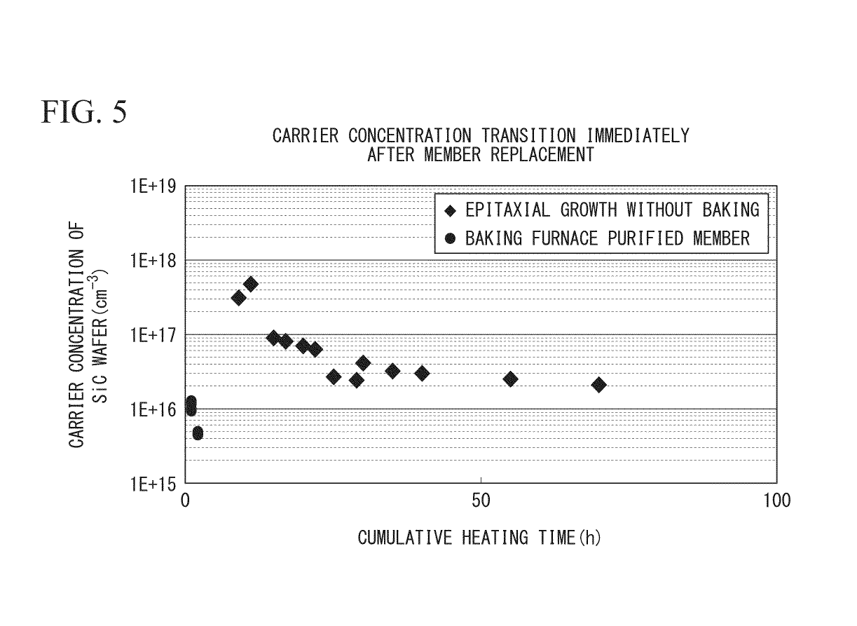

FIG. 5 shows the transitions of the background carrier concentrations of SiC epitaxial wafers when SiC epitaxial films were formed by actually using a coated carbon-based material member which was subjected to vacuum baking and a carbon-based material member which was not subjected to vacuum baking, respectively. At this time, as an SiC epitaxial wafer manufacturing apparatus, a planetary type SiC-CVD growth apparatus manufactured by AIXTRON SE as shown in the schematic diagram of FIG. 4 was used. In this apparatus, the coated carbon-based material members were mainly composed of four types of members consisted of a susceptor unit (denoted by the reference numeral 24 in FIG. 4), satellite units (denoted by the reference numeral 26 in FIG. 4), a sealing unit (denoted by the reference numeral 22 in FIG. 4), and an exhaust ring unit (denoted by the reference numeral 23 in FIG. 4), and a set of all four types of members were subjected to vacuum baking. For the coating, a TaC coating with a thickness of 20 μm was applied. The vacuum baking was carried out using a dedicated baking furnace under conditions of a temperature of 1,500° C. for 200 hours. Epitaxial growth of SiC was carried out at 1,500 to 1,550° C. using H₂ as a carrier gas where the atmosphere pressure thereof was 100 to 200 mmbar.

In the TaC coated carbon-based material member which was not subjected to vacuum baking (denoted as “epitaxial growth without baking” in the legend of FIG. 5), even after the cumulative heating time (integration time of the epitaxial growth) of about 70 hours had passed, the background carrier concentration of the formed SiC wafer was equal to or more than 1.1×10¹⁶ cm⁻³, indicating that the member cannot even be used to produce wafers of a general-purpose specification. On the other hand, in the TaC coated carbon-based material member which was subjected to vacuum baking (described as “purified member in baking furnace”), it became possible to produce wafers of a common product specification (equal to or less than 1.0×10¹⁶ cm⁻³) with the cumulative heating time of about 3 hours (equivalent to two cycles for the epitaxial growth of 6 μm). Furthermore, although not shown in FIG. 5, if the epitaxial growth was carried out repeatedly in a normal cycle, it became possible to produce wafers of a high voltage product specification (equal to or less than 1.2×10¹⁵ cm⁻³) in about one week (it took about one month with the TaC coated carbon-based material member which was not subjected to vacuum baking).

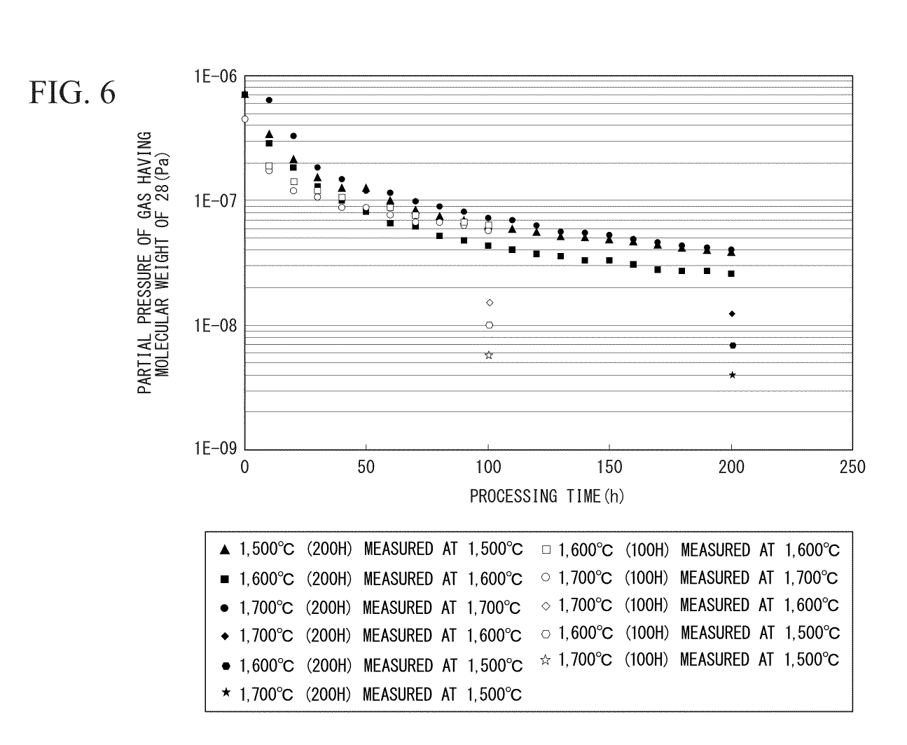

FIG. 6 is a diagram showing the partial pressure of a gas having a molecular weight of 28 (nitrogen) when sets of TaC-coated carbon-based material members (the aforementioned four types of members) were treated by changing the temperature during the vacuum baking which was monitored with a quadrupole mass spectrometer (QMS). The vacuum baking was carried out up to 200 hours at respective temperatures of 1,500° C., 1,600° C. and 1,700° C. In addition, the vacuum baking was also carried out for 100 hours at 1,600° C. and 1,700° C. In order to compare the final nitrogen partial pressure at the same temperature, the nitrogen gas partial pressure was measured for those treated at 1,600° C. when the temperature was lowered to 1,500° C. after the completion of baking for 200 hours and 100 hours, and the nitrogen gas partial pressure was measured for those treated at 1,700° C. when the temperature was lowered to 1,600° C. and 1,500° C. after the completion of baking for 200 hours and 100 hours. These results are shown in the same FIG. 6. For example, those described as “1,700° C. (100 h) measured at 1,600° C.” in the legend show a value obtained by measuring the nitrogen gas partial pressure when the temperature was lowered to 1,600° C. after the vacuum baking of 100 hours at 1,700° C.

From FIG. 6, it is clear that the nitrogen partial pressure decreases as the processing time increases in all conditions. When the nitrogen partial pressures measured in a state where the temperature was lowered to the same temperature (1,500° C.) after the vacuum baking were compared, the higher the baking temperature, the lower the final nitrogen partial pressure. In addition, the final nitrogen partial pressure measured in a state where the temperature was set to the same temperature was lower when the vacuum baking was carried out for 100 hours at 1,700° C. than that when the vacuum baking was carried out for 200 hours at 1,600° C. Thus, it is apparent that it is more effective to increase the temperature than to increase the time for the vacuum baking.

The final ultimate vacuum was 1.07×10⁻⁵ Pa, and the nitrogen gas partial pressure measured in a state where the temperature was set to 1,500° C. was 4.04×10⁻⁹ Pa, when a set of TaC-coated carbon-based material members for the SiC epitaxial wafer manufacturing apparatus was vacuum baked under conditions of 1,700° C. for 200 hours. When the background carrier concentration was evaluated by mounting these sets of TaC-coated carbon-based material members after vacuum baking on the epitaxial wafer manufacturing apparatus and forming an SiC epitaxial film in an undoped manner, a value of 4.27×10¹⁵ cm⁻³ was obtained in step bunching free conditions with a low C/Si ratio. The step bunching refers to a phenomenon in which atomic steps (typically about 2 to 10 atomic layers) are gathered and coalesced on the surface, and may also refer to the steps themselves on the surface. Here, examples of the step bunching free conditions are disclosed, for example, in Japanese Patent No. 4959763 and Japanese Patent No. 4887418.

For comparison, the ultimate vacuum when treated for the same duration at 1,500° C. and 1,600° C. was 1.01×10⁻⁵ Pa and 1.19×10⁻⁵ Pa, respectively, and the nitrogen gas partial pressure measured in a state where the temperature was set to 1,500° C. was 3.89×10⁻⁸ Pa and 7.12×10⁻⁹ Pa, respectively. In addition, the resulting background carrier concentration was 1.02×10¹⁶ cm⁻³ and 8.51×10¹⁵ cm⁻³. Thus, as the processing temperature increased, the nitrogen gas partial pressure decreased, and the background carrier concentration resulted in a favorable value.

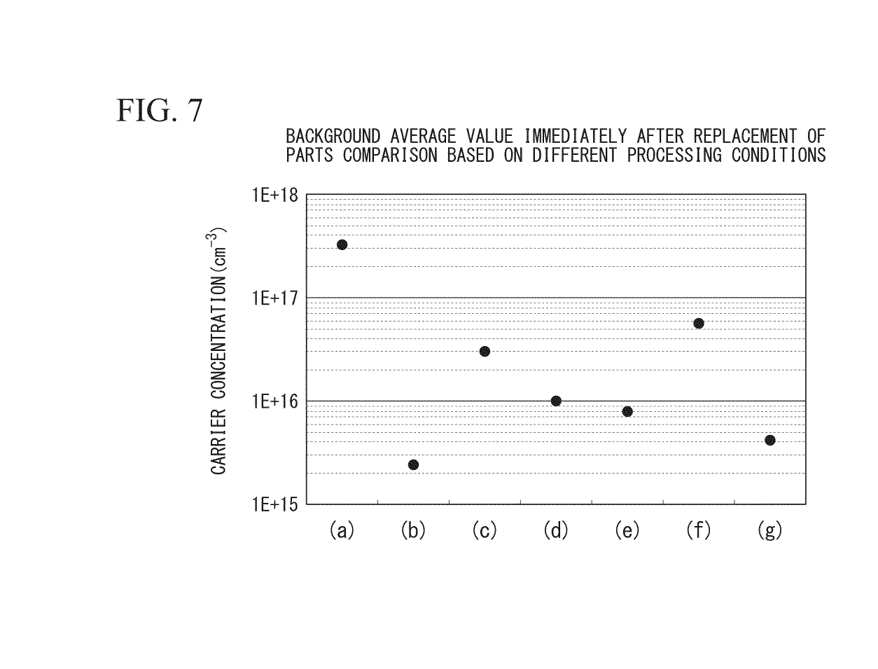

FIG. 7 shows the result of measuring the background carrier concentration by subjecting each of the four types of members described above as the TaC-coated carbon-based material member in the SiC epitaxial wafer manufacturing apparatus to vacuum baking under various conditions, and then mounting the vacuum baked members on the epitaxial wafer manufacturing apparatus and forming an SiC epitaxial film in an undoped manner.

In FIG. 7, (a) is a value obtained when the members are not subjected to vacuum baking (initial state); (b) is a target value immediately after the member replacement; (c) is a value obtained when a set of all four types of members consisted of coated carbon-based material members is subjected to vacuum baking for 100 hours at 1,500° C. in the planetary type SiC-CVD growth apparatus manufactured by AIXTRON SE; (d) is a value obtained when a set of all four types of members consisted of coated carbon-based material members is subjected to vacuum baking for 200 hours at 1,500° C.; (e) is a value obtained when a set of all four types of members consisted of coated carbon-based material members is subjected to vacuum baking for 200 hours at 1,600° C.; (f) is a value obtained in a case where three types of carbon-based members with the exception of the susceptor are subjected to vacuum baking for 200 hours at 1,700° C. while only the susceptor is not subjected to vacuum baking; and (g) is a value obtained when a set of all four types of members consisted of coated carbon-based material members is subjected to vacuum baking for 200 hours at 1,700° C., respectively. These are the background carrier concentrations obtained in the initial SiC epitaxial growth after performing vacuum baking under the respective conditions in a dedicated vacuum baking furnace, respectively using a set of brand new members.

The results showed that the carrier concentration in the initial epitaxial growth decreased, as the baking temperature increased, and also as the baking time increased. In addition, the carrier concentration was high when only the susceptor was not subjected to baking, making it clear that the baking of the susceptor imposes a great influence on the carrier concentration. In other words, among the components in the epitaxial growth apparatus, the effect of the vacuum baking is prominent on the components that are composed of carbon-based materials, increased in temperature during the epitaxial growth, provided with a large volume, and arranged in the vicinity of the epitaxial wafer.

FIG. 8 shows the result of measuring the nitrogen gas partial pressure when the TaC-coated carbon-based material members were subjected to the vacuum baking treatment under conditions of 1,700° C., and 1.4×10⁻⁴ Pa at the start and 3.6×10⁻⁵ Pa at the end. The “Member Set 1” “Member Set 2”, “Member Set 3” and “Member Set 4” in the legend of FIG. 8 are respectively composed of the four types of members (the susceptor 24, the satellites 26, the sealing 22, and the exhaust ring 23, and if there are small components associated with the above members, they are included in the above members and considered as one unit). Therefore, FIG. 8 shows the results of measuring the change in the nitrogen gas partial pressure when four member sets with four types of members were prepared and subjected to vacuum baking.

Although differences were observed in the degree of vacuum and the nitrogen partial pressure at the start of baking at 1,700° C. depending on the members, the ultimate vacuum after performing the vacuum baking treatment for a certain period of time tended to converge to a constant level. This indicates that, although the amount of nitrogen discharged from the brand new, TaC-coated carbon-based material members varied depending on the materials and the history such as storage conditions, by performing vacuum baking under at least certain conditions, it is possible to eliminate this variation, and to reduce variations in the carrier concentrations of the SiC epitaxial layers due to variations in the initial state of the TaC-coated carbon-based material members.

From FIGS. 7 and 8, a processing time of at least 10 hours where the effect of vacuum baking starts to become prominent is preferred. This is because it is considered that the nitrogen gas partial pressure detected by the QMS is reduced to a level of ½ to ¼ in the first 10 hours, and the background carrier concentration is sufficiently reduced. In order to further remove the initial variations of the members, it is more preferable to perform vacuum baking for a processing time of 100 hours or more.

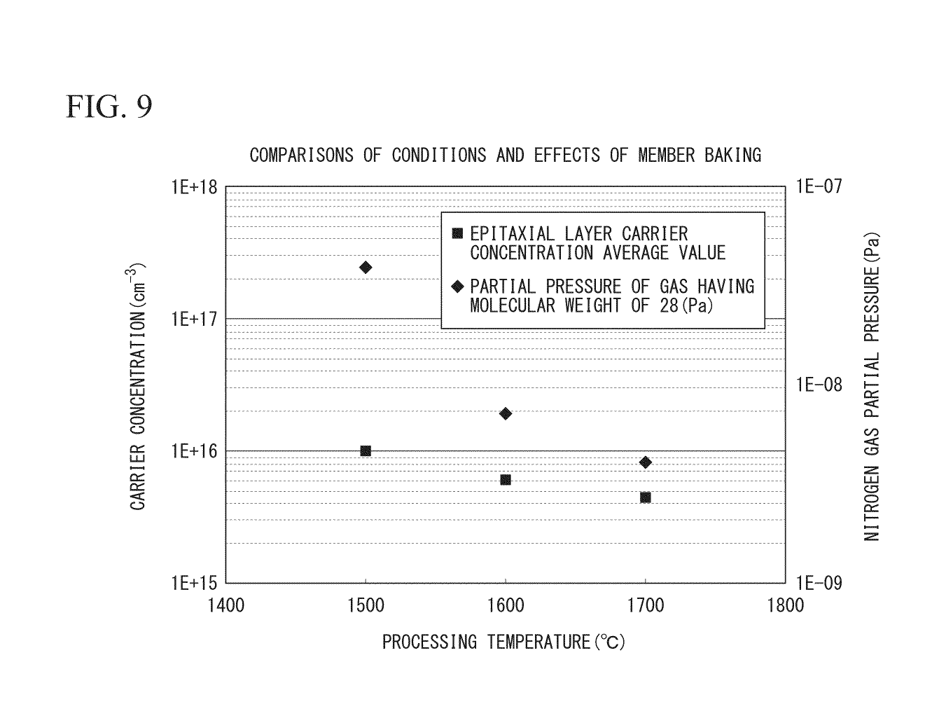

FIG. 9 is a graph showing the dependency of the background carrier concentration of the SiC epitaxial growth layer on the vacuum baking temperature of the TaC-coated carbon-based material members (the four types of members described above), and the final nitrogen partial pressure measured by setting the temperature to 1,500° C. after the vacuum baking.

The vacuum baking was respectively carried out at a degree of vacuum of 1.0×10⁻⁵ Pa for a period of 200 hours. As a result, it is clear that the final nitrogen gas partial pressure decreased as the temperature increased, the background carrier concentration of the SiC epitaxial growth layer dropped in response, and a favorable film was formed.

### REFERENCE SIGNS LIST

1: Chamber;
1a Lid portion;
1b: Main body portion;
1c: Flange portion;
2: Exhaust line;
3: Exhaust system;
4: Quadrupole mass spectrometer (QMS);
5: Shielding plate;
6: Heater;
6a: IN-side heater;
6b: OUT-side heater;
7: Tray;
8: Rail;
10: Dedicated baking furnace;
20: CVD (chemical vapor deposition) apparatus;
21: Mounting plate;
22: Sealing;
23: Exhaust ring;
24: Susceptor;
25: Rotating shaft;
26: Satellite;
27: Accommodating portion;
29: Induction coil;
30: Gas introduction tube;
30a: Flange portion;
31: Support ring;
W: Wafer;
G: Raw material gas

1. A method for producing an SiC epitaxial wafer, the method comprising:
a step of vacuum baking a coated carbon-based material member at a degree of vacuum of 2.0×10⁻³ Pa or less in a dedicated vacuum baking furnace;
a step of installing the coated carbon-based material member in an epitaxial wafer manufacturing apparatus; and
a step of placing an SiC substrate in the epitaxial wafer manufacturing apparatus and epitaxially growing an SiC epitaxial film on the SiC substrate.

2. The method for producing an SiC epitaxial wafer according to claim 1, wherein the degree of vacuum is 1.0×10⁻⁵ Pa or less.

3. The method for producing an SiC epitaxial wafer according to claim 1, wherein the vacuum baking is carried out at a temperature of 1,400° C. or higher.

4. The method for producing an SiC epitaxial wafer according to claim 1, wherein the vacuum baking is carried out for at least 10 hours.

5. The method for producing an SiC epitaxial wafer according to claim 1,
wherein the vacuum baking is carried out until a nitrogen partial pressure at 1,500° C. is 1.0×10⁻⁷ Pa or less.

6. The method for producing an SiC epitaxial wafer according to claim 1,
wherein the coated carbon-based material member comprises one selected from the group consisting of a susceptor, a satellite, a sealing, and an exhaust ring.

7. The method for producing an SiC epitaxial wafer according to claim 1, wherein the coating is formed using TaC or SiC.
